(19) United States
(12) Patent Application Publication
(10) Pub. No.: US 2019/0267605 A1
(43) Pub. Date: Aug. 29, 2019

(54) POWER SUPPLY DEVICE

(71) Applicant: KEIHIN CORPORATION, Tokyo (JP)

(72) Inventor: Seiji KAMATA, Utsunomiya-shi (JP)

(21) Appl. No.: 16/348,631

(22) PCT Filed: Nov. 2, 2017
(86) PCT No.: PCT/JP2017/039715

§ 371 Date: May 9, 2019

(30) Foreign Application Priority Data
Nov. 15, 2016 (JP) 2016-222277

(51) Int. Cl. H01M 2/34; H01M 10/48; H01M 10/44; H02H 7/18; H02J 7/02; H02J 7/00; H01M 2/10; G01R 31/3842; B60L 3/04; B60L 58/10

(52) U.S. Cl. CPC H01M 2/345; H01M 10/482; H01M 10/44; H02H 7/18; B60L 58/10; H02J 7/0031; H01M 2/1077; G01R 31/3842; B60L 3/04; H02J 7/02

(57) ABSTRACT

An electric power supply system for supplying a load device with driving electric power includes an electric power storage device and an ECU. The electric power storage device includes a CID configured to interrupt an electrical conduction path of the electric power storage device in response to the electric power storage device having an internal pressure exceeding a rated value. The controller calculates a voltage variation length corresponding to an integral of an amount by which a voltage applied to the load device varies in magnitude and a current variation length corresponding to an integral of an amount by which a current input/output to/from the electric power storage device varies in magnitude for each sampling period for a predetermined period of time. Then, the ECU determines whether or not the CID has been operated, based on the voltage variation length and the current variation length.

### TECHNICAL FIELD

The present invention relates to a power supply device.

Priority is claimed on Japanese Patent Application No. 2016-222277, filed on Nov. 15, 2016, the content of which is incorporated herein by reference.

### BACKGROUND ART

In recent years, power supply devices installed in vehicles or the like have included battery pack having a plurality of battery cells connected in series and voltage detection devices which detect a voltage of each of the battery cells. As described in, for example, Patent Document 1, the battery cells have a current interrupt device (CID) built thereinto.

This CID is a mechanism for stopping charging and discharging by battery cells in which an abnormality has occurred by shutting off a conduction path inside each of the battery cells when the internal pressure of the battery cell increases due to overcharging or the like. For example, as described in Patent Document 1, such a CID is built into each of a plurality of battery cells included in a battery.

### CITATION LIST

### [Patent Document]

### [Patent Document 1]

Japanese Patent No. 5556902

### SUMMARY OF INVENTION

### Technical Problem

However, when a CID is built into a battery cell, it is necessary to secure an installation space for the CID inside the battery cell. Thus, a size of the battery cell is increased. On the other hand, in order to build a CID into a battery cell without changing a size of an outer shape of the battery cell, an accommodation space for an electrolytic solution and the like is reduced and the battery capacity of the battery cell is reduced. In an electric vehicle (EV) and a plug-in hybrid vehicle (PHV), it is necessary to install a battery in a limited accommodation space. Thus, it is necessary to increase the battery capacity of each of the battery cells as much as possible to miniaturize a battery pack or increase the battery capacity of the battery pack as a whole.

An aspect of the present invention has been realized in view of the above-described problems, and an objective of the present invention is to provide a power supply device with battery pack having a plurality of battery cells and voltage detection devices which detect a voltage of each of the battery cells, in which it is possible to reduce a size of a battery pack or to increase the battery capacity of the battery pack as a whole.

### Solution to Problem

In order to solve the above technical problems and accomplish the above objective, the present invention adopts the following aspects.

(1) A power supply device according to an aspect of the present invention is a power supply device which includes a battery pack having a plurality of battery cells and a voltage detection device which detects a voltage of each of the battery cells, wherein: the battery pack includes a plurality of battery modules each formed by connecting a plurality of the battery cells in series, and at least one of the battery modules of the battery pack includes only one battery cell having a shutoff device installed therein which shuts off a conduction path based on an increase in an internal pressure of the battery cell.

(2) In the aspect (1), only one of the battery cells having the shutoff device built thereinto may be provided in the battery pack.

(3) In the aspect (1), one of the battery cells having the shutoff device built thereinto may be provided for each of the battery modules.

(4) A power supply device according to an aspect of the present invention is a power supply device which includes a battery pack having a plurality of battery cells and a voltage detection device which detects a voltage of each of the battery cells, wherein: a shutoff device which shuts off a conduction path based on an increase in an internal pressure of the battery cells is built into only a battery cell having the smallest battery capacity among the plurality of battery cells belonging to one group.

(5) A power supply device according to an aspect of the present invention is a power supply device which includes a battery pack having a plurality of battery cells and a voltage detection device which detects a voltage of each of the battery cells, provided with: at least one battery cell which does not have a shutoff device configured to shut off a conduction path based on an increase in an internal pressure of the battery cells built thereinto.

### Advantageous Effects of Invention

According to an aspect of the present invention, at least one of a plurality of battery cells included in a battery pack does not have a current interrupt device (CID) built thereinto. A battery cell which does not have a CID built thereinto can be downsized or have an increased battery capacity. Therefore, according to an aspect of the present invention, in a power supply device which includes a battery pack having a plurality of battery cells and voltage detection devices which detect a voltage of each of the battery cells, it is possible to reduce a size of the battery pack or to increase a battery capacity of the entire battery pack.

### BRIEF DESCRIPTION OF DRAWINGS

FIG. 1 is a functional block diagram illustrating a schematic configuration of a power supply device according to a first embodiment of the present invention.

FIG. 2 is a functional block diagram illustrating a schematic configuration of a power supply device according to a second embodiment of the present invention.

### DESCRIPTION OF EMBODIMENTS

An embodiment of a power supply device of the present invention will be described below with reference to the drawings. Note that, in the following drawings, in order to make each member have a recognizable size, the scales of respective members may be appropriately modified.

### First Embodiment

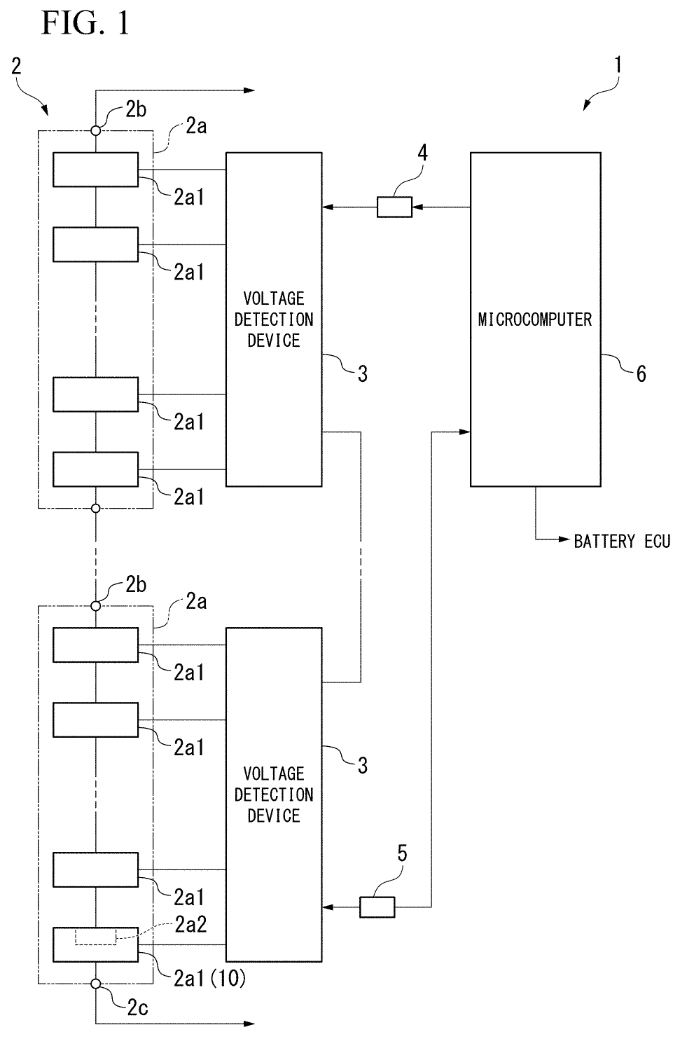

FIG. 1 is a functional block diagram illustrating a schematic configuration of a power supply device 1 in this embodiment. As illustrated in FIG. 1, the power supply device 1 in this embodiment includes a battery pack 2, voltage detection devices 3, a first insulating element 4, a second insulating element 5, and a microcomputer 6.

The battery pack 2 is formed by connecting a plurality of battery modules 2a in series.

It should be noted that, although the battery pack 2 is configured to include a plurality of battery modules 2a in this embodiment, the battery pack 2 may be configured of a single battery module 2a. Such a battery pack 2 includes a pair of output terminals (that is, a plus terminal 2b and a minus terminal 2c), is connected to an inverter via a connector (not shown), and is connected to a traveling motor via the inverter.

As illustrated in FIG. 1, each of the battery modules 2a includes a plurality of battery cells 2a1 connected in series. In this way, in the power supply device 1 in this embodiment, the battery pack 2 has a configuration in which a plurality of battery modules 2a having a plurality of battery cells 2a1 connected in series are connected in series. That is to say, the battery pack 2 has a configuration in which a plurality of battery cells 2a1 are connected in series.

In the power supply device 1 in this embodiment, a current interrupt device (CID) 2a2 (a shutoff device) is built into only one battery cell 2a1 among the plurality of battery cells 2a1 included in the battery pack 2. That is to say, the CID 2a2 is built into only one battery cell 2a1 among the plurality of battery cells 2a1 belonging to one group constituting the battery pack 2.

The CID 2a2 is a mechanism which mechanically shuts off a conduction path inside the battery cell 2a1 when the internal pressure of the battery cell 2a1 increases due to overcharging or the like. For example, when the internal pressure of the battery cell 2a1 reaches an abnormally high pressure, the CID 2a2 may mechanically open one of output terminals (a plus terminal and a minus terminal) of the battery cell 2a1. When the CID 2a2 operates and a conduction circuit inside the battery cell 2a1 is shut off, the battery pack 2 is brought into a state in which direct current (DC) power cannot be supplied to the outside.

In this embodiment, the battery cell 2a1 (hereinafter referred to as a CID built-in battery cell 10) having the CID 2a2 built thereinto has the smallest battery capacity among all of the battery cells 2a1 included in the battery pack 2. It should be noted that the CID built-in battery cell 10 has the same outer shape as the other battery cells 2a1 which do not include a CID 2a1 built thereinto and the capacity thereof is reduced by reducing an accommodation space for an electrolytic solution according to an amount due to building in the CID 2a2. That is to say, in this embodiment, the battery capacity of the CID built-in battery cell 10 is intentionally set to be smaller than those of the other the battery cells 2a1. In this way, by making the outer shape of the CID built-in battery cell 10 have the same shape as the other battery cells 2a1, the shapes of the battery module 2a which includes the CID built-in battery cell 10 and the battery module 2a which does not include the CID built-in battery cell 10 can be made to the same and an attaching structure and the like for the battery modules 2a can be shared.

It should be noted that it is desirable that the CID built-in battery cell 10 be disposed at the lowest potential position among all of the battery cells 2a1. That is to say, in this embodiment, it is desirable that the battery cell 2a1 disposed closest to the minus terminal 2c among the battery pack 2 illustrated in FIG. 1 be the CID built-in battery cell 10. In this way, by disposing the CID built-in battery cell 10 at the lowest potential position, it is easy to adjust the level of a signal when detecting an abnormal voltage in a case in which the CID 2a2 is operating, and it becomes possible to detect an abnormal voltage with a simple circuit configuration.

Also, it is desirable that the CID built-in battery cell 10 be disposed at a position with the lowest cooling efficiency among all of the battery cells 2a1. For example, when all of the battery cells 2a1 are disposed in a flow path of the cooling air, the temperature of the cooling air gradually increases due to the cooling of the battery cells 2a1. Thus, the cooling efficiency is the lowest at the side furthest downstream in a flow of the cooling air. Therefore, it is desirable that the CID built-in battery cell 10 be disposed at the side furthest downstream in the flow of the cooling air.

Generally, the battery cell 2a1 installed at a location with the lowest cooling efficiency has a faster rate of deterioration than other battery cells 2a1 and an increase in internal pressure readily occurs therein. For this reason, by disposing the CID built-in battery cell 10 at a position in which an increase in internal pressure is highly likely to occur, the CID built-in battery cell 10 will exhibit an abnormality earlier than other battery cells 2a1 and it will thus be possible to more reliably determine an abnormality in the battery pack 2.

Each of the voltage detection devices 3 is a circuit which detects an output voltage of the battery pack 2. In addition, in this embodiment, a voltage detection device 3 is provided for each of the battery modules 2a. Each of the voltage detection devices 3 is connected to an output terminal of the battery cells 2a1 in the battery module 2a and detects an output voltage of each of the battery cells 2a1. It should be noted that it is also possible to provide a plurality of voltage detection devices 3 for each of the battery modules 2a or for them to bridge between a plurality of battery modules 2a. The voltage detection devices 3 are connected to the microcomputer 6 via the first insulating element 4 and the second insulating element 5 using a so-called daisy chain method. The voltage detection devices 3 output a signal indicating the output voltage of each of the connected battery cells 2a1 to the microcomputer 6.

The first insulating element 4 is disposed between the output terminal of the microcomputer 6 and the voltage detection device 3 on the side furthest upstream in a transmission direction of the signal when viewed from the microcomputer 6 among the plurality of the voltage detection devices 3. The second insulating element 5 is disposed between the input terminal of the microcomputer 6 and the voltage detection device 3 on the side furthest downstream in the transmission direction of the signal when viewed from the microcomputer 6 among the plurality of the voltage detection devices 3. The first insulating element 4 and the second insulating element 5 are elements which electrically insulate the voltage detection devices 3 and the microcomputer 6 from each other by preventing direct electrical connection therebetween. For the first insulating element 4 and the second insulating element 5, photocouplers which convert an electrical signal into an optical signal and then immediately convert the optical signal into an electrical signal again are used.

The microcomputer 6 has a central processing unit (CPU), a memory, an input/output interface, and the like integrally incorporated therein and is formed of a one-chip microcomputer. The microcomputer 6 executes a voltage detection program stored in an internal memory to perform a voltage detection function of the battery pack 2. To be more specific, the microcomputer 6 converts the output voltage of each of the battery cells 2a1 input from the voltage detection device 3 into a digital value, performs predetermined calculation on the digital value and outputs the value to a battery ECU.

In the power supply device 1 in this embodiment having such a configuration, a command signal is output from the microcomputer 6 and the command signal is input to the voltage detection device 3 via the first insulating element 4. The voltage detection devices 3 detects a voltage of the battery cell 2a1 on the basis of the command signal and outputs a detection signal indicating the detection result. The detection signal output from the voltage detection device 3 is input to the microcomputer 6 via the second insulating element 5. The microcomputer 6 performs a predetermined calculation on the input detection signal and outputs the signal to the battery ECU. On the other hand, when the CID 2a2 is operating, an overvoltage is output from the battery pack 2 and a signal indicating this is input to the microcomputer 6 through the voltage detection device 3.

According to the power supply device 1 in this embodiment as described above, among a plurality of battery cells 2a1 included in the battery pack 2, the many of the battery cells 2a1 excluding one battery cell 2a1 (the CID built-in battery cell 10) do not have a CID 2a2 built thereinto. Since the battery cell 2a1 which does not have the CID 2a2 built thereinto has the same outer shape as the CID built-in battery cells 10, it is possible to increase the battery capacity. Therefore, according to the power supply device 1 in this embodiment, it is possible to increase the battery capacity of the battery pack 2 as a whole.

It should be noted that, although a configuration in which it is possible to increase the battery capacity by making the battery cell 2a1 which does not have the CID 2a2 have the same outer shape as the CID built-in battery cells 10 is provided in the power supply device 1 in this embodiment, it is also possible to make the battery capacity of the battery cell 2a1 which does not have the CID 2a2 built thereinto be the same as the CID built-in battery cells 10 and it is also possible to reduce a size of the battery cell 2a1 which does not have the CID 2a2 built thereinto by an extent that the CID 2a2 is omitted. In such a case, a compact battery pack 2 can be realized.

Also, in the power supply device 1 in this embodiment, only one CID built-in battery cell 10 is provided for the entire battery pack 2 constituted of a plurality of battery modules 2a. For this reason, in the battery pack 2, it is possible to maximize the number of battery cells 2a1 which do not include the CID 2a2 and to maximize the battery capacity of the battery pack 2.

Furthermore, in the power supply device 1 in this embodiment, the CID 2a2 is built into the battery cell 2a1 having the smallest battery capacity among the battery cells 2a1 included in the battery pack 2. The battery cell 2a1 having the smallest battery capacity becomes overcharged earlier than the other battery cells 2a1 and the internal pressure thereof increases faster than the other battery cells 2a1. That is to say, in the power supply device 1 in this embodiment, the CID 2a2 is built into the battery cell 2a1 having the highest probability of abnormality occurrence. For this reason, it is possible to reliably determine an abnormality in the battery pack 2.

### Second Embodiment

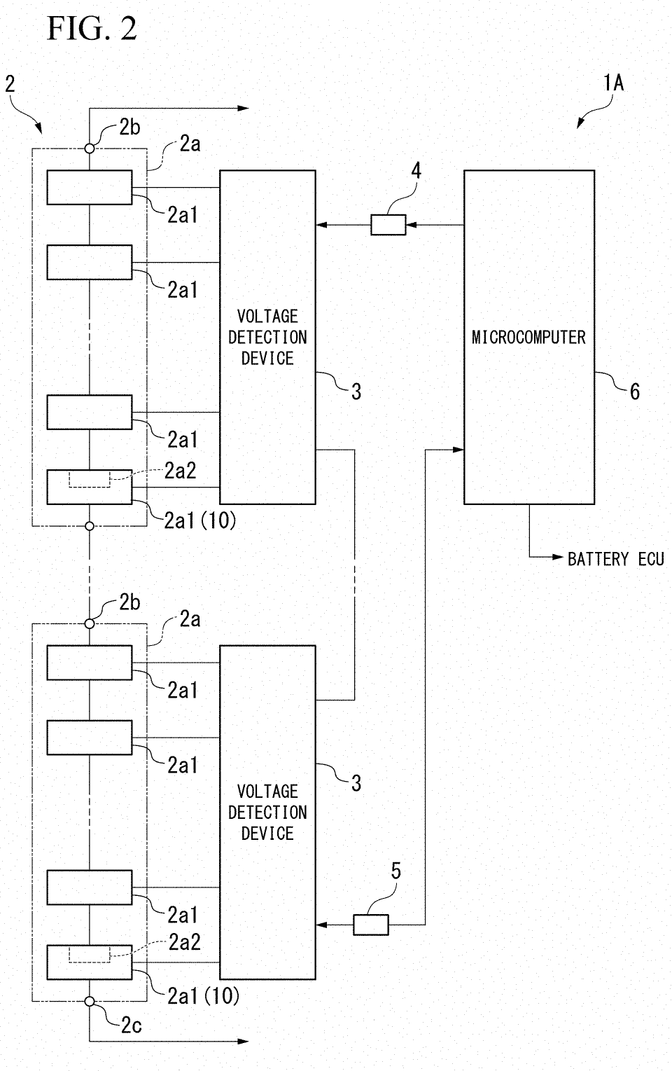

A second embodiment of the present invention will be described below with reference to FIG. 2. It should be noted that, in the description of this embodiment, description of constituent elements that are the same as those of the first embodiment will be omitted or simplified.

FIG. 2 is a functional block diagram illustrating a schematic configuration of a power supply device 1A according to this embodiment. As illustrated in FIG. 2, in the power supply device 1A in this embodiment, the CID built-in battery cell 10 is provided for each of a plurality of battery modules 2a constituting the battery pack 2. That is to say, the present invention is not limited to a structure in which only one CID built-in battery cell 10 is provided in the battery pack 2. The present invention may adopt a configuration in which a plurality of CID built-in battery cells 10 are provided in the battery pack 2 as in this embodiment.

It should be noted that, in the power supply device 1 in this embodiment, it is desirable to provide the CID built-in battery cells 10 at the same positions in all of the battery modules 2a. By adopting such a configuration, it is possible to make all of the battery modules 2a have the same configuration and the manufacturability of the battery module 2a and the assembling workability of the battery pack 2 are then improved.

Although the preferred embodiments of the present invention have been described above with reference to the accompanying drawings, it is needless to say that the present invention is not limited to the above embodiments. The shapes and combinations of the constituent elements illustrated in the above-described embodiments are merely examples and various modifications can be provided on the basis of design requirements and the like without departing from the gist of the present invention.

For example, in the above-described embodiments, a configuration in which one CID built-in battery cell 10 is provided in the battery pack 2 or the battery module 2a is adopted. However, the present invention is not limited to this configuration. For example, it is also possible to adopt a configuration in which a plurality of CID built-in battery cells 10 are provided in one battery module 2a. For example, in the present invention, it is also possible to make all of the other battery cells 2a1 except for one battery cell 2a1 be CID built-in battery cells 10.

### REFERENCE SIGNS LIST

1 Power supply device
1A Power supply device
2 Battery pack
2a Battery module
2a1 Battery cell
2a2 CID (shutoff device)
3 Voltage detection device
10 Built-in battery cell

1. A power supply device which includes a battery pack having a plurality of battery cells and a voltage detection device which detects a voltage of each of the battery cells, wherein:
the battery pack includes a plurality of battery modules each formed by connecting the plurality of battery cells in series, and at least one of the battery modules of the battery pack includes only one battery cell having a shutoff device installed therein which shuts off a conduction path based on an increase in an internal pressure of the battery cell.

2. The power supply device according to claim 1, wherein only one of the battery cells having the shutoff device built thereinto is provided in the battery pack.

3. The power supply device according to claim 1, wherein one of the battery cells having the shutoff device built thereinto is provided for each of the battery modules.

4. A power supply device which includes a battery pack having a plurality of battery cells and a voltage detection device which detects a voltage of each of the battery cells, wherein:
a shutoff device which shuts off a conduction path based on an increase in an internal pressure of the battery cells is built into only a battery cell having the smallest battery capacity among the plurality of battery cells belonging to one group.

5. A power supply device which includes a battery pack having a plurality of battery cells and a voltage detection device which detects a voltage of each of the battery cells, comprising:
at least one battery cell which does not have a shutoff device configured to shut off a conduction path based on an increase in an internal pressure of the battery cells built thereinto.
